(19) United States
(12) Patent Application Publication
(10) Pub. No.: US 2018/0096946 A1
(43) Pub. Date: Apr. 5, 2018

(54) SEMICONDUCTOR PACKAGES HAVING A FIDUCIAL MARKER AND METHODS FOR ALIGNING TOOLS RELATIVE TO THE FIDUCIAL MARKER

(71) Applicant: Intel Corporation, Santa Clara, CA (US)

(72) Inventors: John G. Meyers, Sacramento, CA (US); Hyoung Il Kim, Folsom, CA (US); Yong She, Folsom, CA (US)

(73) Assignee: Intel Corporation, Santa Clara, CA (US)

(21) Appl. No.: 15/282,754

(22) Filed: Sep. 30, 2016

(51) Int. Cl. H01L 23/544; H01L 25/065; H01L 25/00; H01L 21/56; H01L 21/027

(52) U.S. Cl. CPC H01L 23/544; H01L 25/0657; H01L 25/50; H01L 21/563; H01L 2223/54426; H01L 2225/06562; H01L 2225/06548; H01L 2225/0651; H01L 21/0274

(57) ABSTRACT

Electronic device package technology is disclosed. In one example, an electronic device includes a plurality of dies stacked on a substrate and a reference die on the plurality of dies and having a fiducial marker that indicates a spatial position of the plurality of dies for alignment of an electronics assembly tool. The fiducial marker can comprise a physical alteration of the reference die, such as indicia that is sawed or laser/plasma/chemical etched. A transparent dielectric layer is disposed on the reference die such that the tool can locate the fiducial marker in three dimensional space through the transparent layer. The dielectric layer is etched corresponding to a photomask after a photoresist is disposed on the dielectric layer. The etched dielectric layer comprises at least one redistribution layer electrically coupled to the vertical wire interconnect structure to provide an ultra-thin package. A method of aligning an electronics assembly tool is disclosed.

### TECHNICAL FIELD

Embodiments described herein relate generally to electronic devices, and more particularly to a electronic devices having a fiducial marker to align an electronics assembly tool.

### BACKGROUND

During semiconductor assembly processes, the ability to precisely place or align a developing workpiece within processing equipment is extremely important. Many semiconductor devices include a stack of dies with a vertical wire interconnect along a top layer. In some cases, it may be desirable to top the stack with a layer of material that allows electrical connection with the vertical wires extending upward from each die in the stack, or with another layer of material or a non-functional die (e.g. a “dummy die”). Because such a layer or dummy die does not contain the features of other dies, once encapsulation molding and polishing has occurred, there are no persisting indicators that can be used for three-dimensional alignment of the device with additional tools and equipment in the downstream fabrication process.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1 shows a schematic of an electronic device in accordance with an example;

FIG. 2A shows a schematic of a method of fabricating an electronic device in accordance with an example;

FIG. 2B shows a schematic of the method continued from FIG. 2A in accordance with an example;

FIG. 3 shows a top view of an electronic device in accordance with an example;

FIG. 4 shows a top and side cross sectional view an electronic device in accordance with an example;

FIG. 5 shows a bottom and side view an electronic device in accordance with an example;

FIG. 6 illustrates a method in accordance with an example;

FIG. 7 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” include support for plural referents unless the context clearly dictates otherwise. Thus, for example, reference to “a layer” includes support for a plurality of such layers.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in this written description, like “comprising” or “including,” it is understood that direct support should be afforded also to “consisting essentially of” language as well as “consisting of” language as if stated explicitly and vice versa.

The terms “first,” “second,” “third,” “fourth,” and the like in the written description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the written description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” is defined as actual physical contact between two objects, structures, or items. Objects described herein as being “adjacent to” each other may be in physical contact with each other, in close proximity to each other, or in the same general region or area as each other, as appropriate for the context in which the phrase is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. It is understood that express support is intended for exact numerical values in this specification, even when the term “about” is used in connection therewith.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular component, structure, or characteristic described in connection with the example is included in at least one embodiment. Thus, appearances of the phrases “in an example” in various places throughout this specification are not necessarily all referring to the same embodiment. Occurrences of the phrase “in one embodiment,” or “in one aspect,” herein do not necessarily all refer to the same embodiment or aspect.

Furthermore, the described components, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in device or machine language, if desired. In any case, the language may be a compiled or interpreted language, and combined with hardware implementations.

### EXAMPLE EMBODIMENTS

An initial overview of technology embodiments is provided below and specific technology embodiments are then described in further detail. This initial summary is intended to aid readers in understanding the technology more quickly but is not intended to identify key or essential components of the technology nor is it intended to limit the scope of the claimed subject matter.

Because of the need for precise alignment of a developing semiconductor workpiece with fabrication equipment, it is important at each fabrication stage to have workpiece features or parts exposed that provide a visual identifier for downstream equipment to use as an alignment que when receiving the workpiece. In some cases, a prior process step may not leave any such features or parts exposed for alignment purposes in a subsequent step. Accordingly, in one embodiment, an electronic device is disclosed that comprises a substrate, a plurality of dies stacked on the substrate, and a reference die stacked on the plurality of dies. The reference die can include a fiducial marker that indicates a spatial position of the plurality of dies for alignment of an electronics assembly tool. The fiducial marker can comprise a physical alteration of a surface of the reference die, such as at least one indicia that is sawed, laser etched, chemically etched, and/or plasma etched into or onto the reference die. A transparent dielectric layer can be disposed on the reference die such that the fiducial marker is locatable by the electronics assembly tool. The electronics device can include a vertical wire interconnect structure coupled to the plurality of dies. The dielectric layer can be etched corresponding to a photomask after a photoresist is disposed on the dielectric layer, such as during a lithography process by a lithography tool as part of a system. The etched dielectric layer can comprise at least one redistribution layer electrically coupled to the vertical wire interconnect structure.

In addition, there is provided methods of aligning an electronics assembly tool with an electronics assembly. In one embodiment, such a method comprises: providing an electronics device and depositing an encapsulation material about the electronics device; polishing the encapsulation material and the reference die after curing the encapsulation material; depositing a dielectric layer on the reference die; depositing a photoresist material on the dielectric layer, wherein the electronics assembly tool comprises a lithography tool utilizing a photomask and the photoresist material; aligning the photomask with the lithography tool relative to the fiducial marker on the reference die; etching the dielectric layer relative to a trace pattern corresponding to the photomask, thereby removing the photoresist; plating the dielectric layer, thereby forming a redistribution layer electrically connected to the plurality of dies.

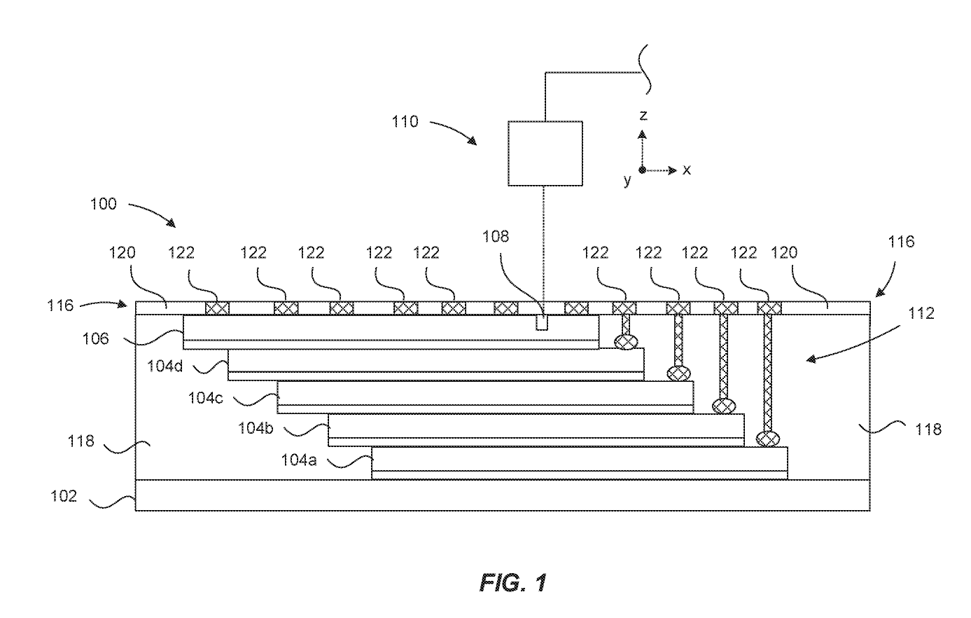

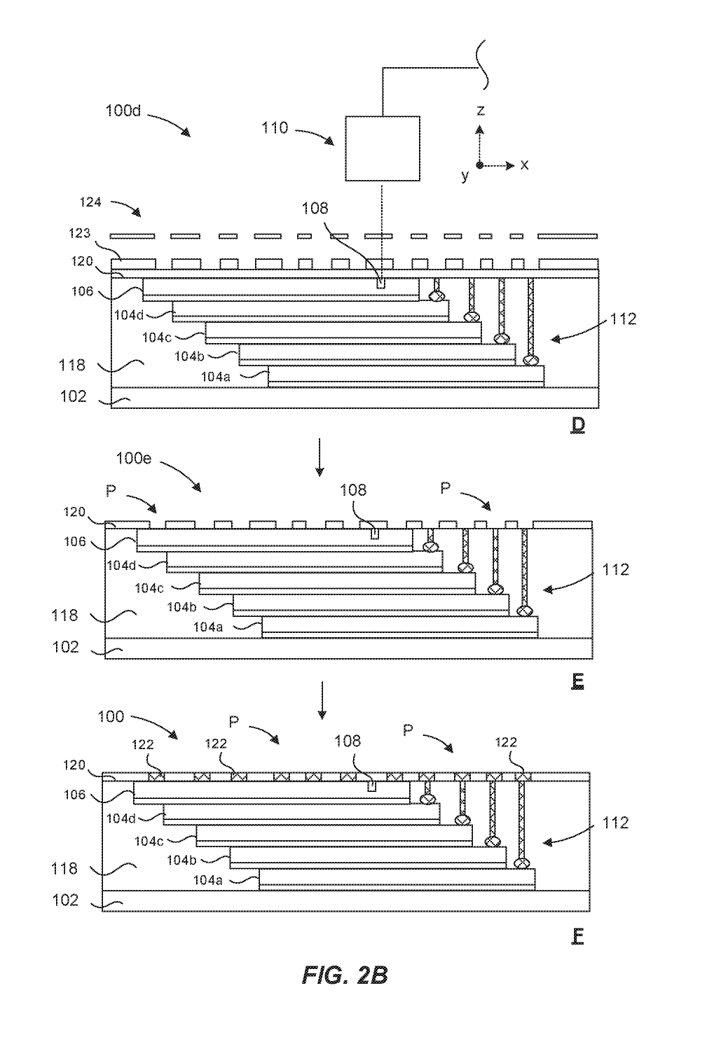

FIG. 1 shows an electronics device 100 comprising a substrate 102 (e.g., a temporary carrier) and a plurality of dies 104a-d stacked on the substrate 102. A reference die 106 is stacked on the plurality of dies 104a-d (specifically, stacked on die 104d). The reference die 106 comprises a fiducial marker 108 that indicates a spatial position of the plurality of dies 104a-d for three dimensional spatial alignment of an electronics assembly tool 110, such as a lithography tool utilizing a photomask (see FIGS. 3, 4, and 5 for further discussion of fiducial marker(s)). In this example, the fiducial marker 108 is a sawed cut formed vertically and partially through the reference die 106 (which can be a dummy die). The electronics device 100 includes a vertical wire interconnect structure 112 having conductive columns electrically coupled to respective dies 104a-d and to respective redistribution traces 122 of a redistribution layer 116. An encapsulation material 118 is deposited about the vertical wire interconnect structure 112 and the dies 104a-d and 106. An etched, transparent dielectric layer 120 is disposed adjacent the reference die 106, and redistribution traces 122 are etched through the dielectric layer 120, such as performed during a redistribution layering process. Accordingly, a plurality of such redistribution layers may be disposed on the electronic device 100, as generally with implemented with typical semiconductor packages.

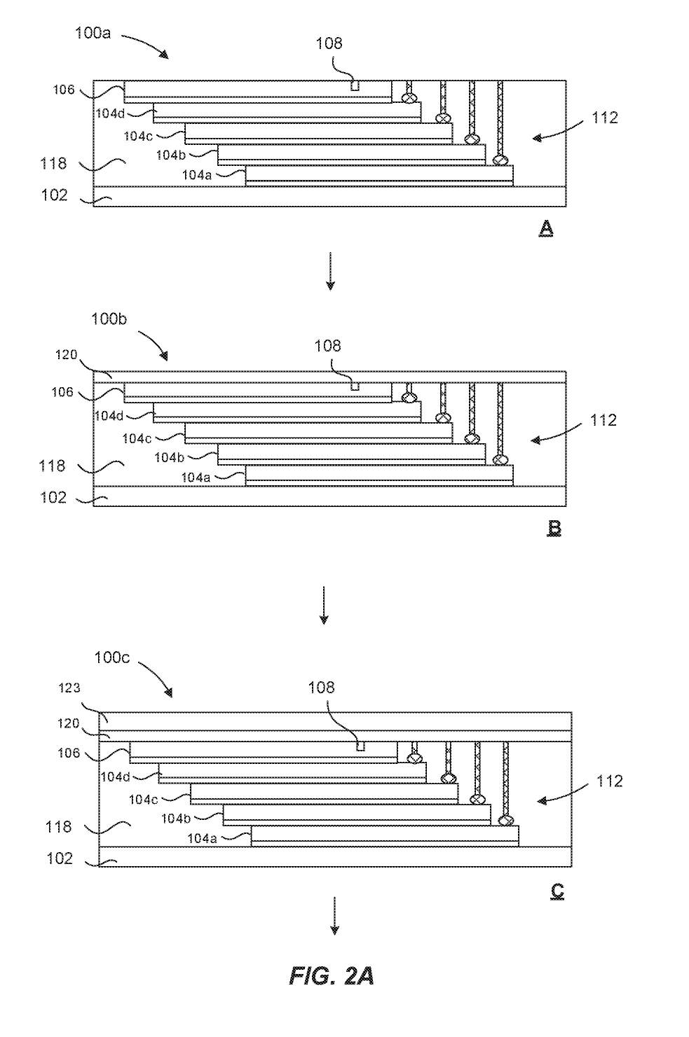

FIGS. 2A and 2B illustrate a method of making the electronics device 100 and a method of aligning the electronics assembly tool 110. Both methods are exemplified by reference labels A-E adjacent each schematic illustration, showing significant process steps to create the electronics device 100. Specifically, at step A there is provided an electronics assembly 100a having a substrate 102 with the plurality of dies 104a-d and a reference die 106 stacked thereon. A fiducial marker 108 can be formed on (or otherwise imparted onto) the reference die 106 before or after being stacked on die 104d. Here, the fiducial marker 108 is a sawed cut on the reference die 106 at a particular, predetermined location on the reference die 106, and, the reference die 106 is attached to die 104d at a predetermined location. Thus, the exact three dimensional spatial location of the fiducial marker 108 is known and viewable by the electronics assembly tool 110, as illustrated by the dashed line on FIG. 1 and step D of FIG. 2B (see below discussion). To obtain the configuration of the electronic device 100a at step A, the encapsulation material 118 and the reference die 106 (and the interconnect structure 112) have been ground or polished down to a certain z-height.

At step B, the dielectric layer 120 is disposed (e.g., spin coated) on top and adjacent the reference die 106. The dielectric layer 120 can be comprised of a semi-transparent or transparent material such that the electronics assembly tool 110 can visually locate the fiducial marker 108 (see step D). Visually locating an indicia or other marker, such as with a photo sensor, infrared camera, or other device on an assembly tool, is generally known and will not be discussed in detail. However, it will be appreciated that the assembly tool 110 will have a photo sensor, infrared camara, or other device to visually or otherwise locate the position of the fiducial maker.

At step C, a photoresist material 123 is disposed (e.g., spin coated) on top and adjacent the dielectric layer 120. With continued reference to FIG. 2B, at step D a photomask 124 is positioned adjacent the photoresist layer 123 by the electronics assembly tool 110 (e.g., a lithography device). The photomask 124 is positioned at a particular location relative to the (located) fiducial marker 108. Accordingly, because the position of the fiducial marker 108 is known, the electronics assembly tool 110 can be properly positioned in three-dimensional space relative to the fiducial marker 108. Then, the photomask 124 can be precisely placed in its desired location relative to the plurality of dies 104a-d (and consequently the interconnect structure 112 of the device 100d). Once the photomask 124 is precisely located relative to the device 100d, the electronics assembly tool 110 can perform one or more operations. For instance, the tool 110 can be a lithography tool that exerts radiation (e.g., a light source) above the photomask 124 and through the exposed locations onto the photoresist material to create a trace pattern, such as with typical lithography processes. At step E, an etching tool (not shown) can etch the dielectric layer 120 relative to a desired trace pattern P and remove the photoresist layer 123, as shown by the resulting configuration of device 100e. At step F, the electronic device 100 of FIG. 1 is formed by a redistribution layer tool (not shown) that performs a plating process to form traces 122 (only a few labeled) about the desired trace pattern P of the dielectric layer 120 to electrically couple the interconnect structure to said traces 122, for instance. The plating process can be an electroless plating process. Steps B through F can be repeated to form a plurality of redistribution layers on the electronic device 100.

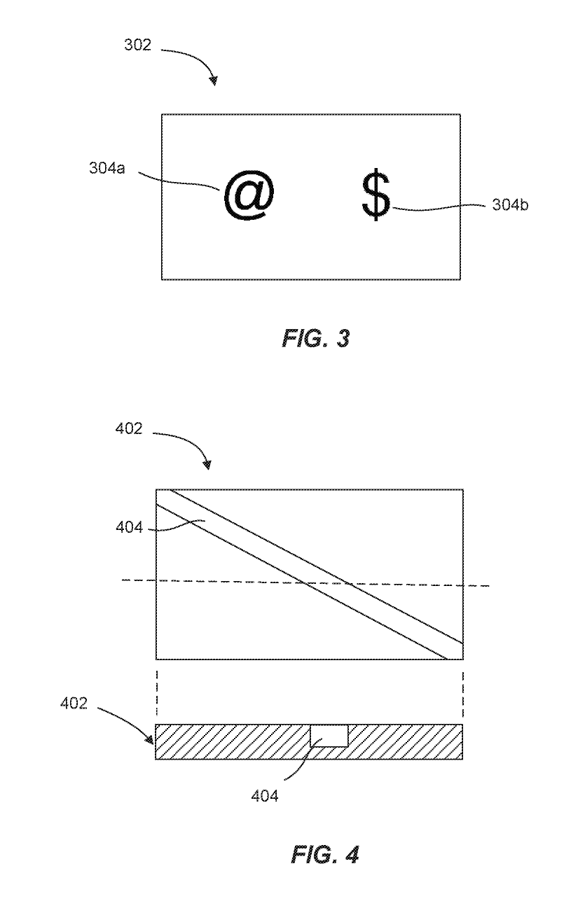

FIGS. 3, 4, and 5 show some examples of fiducial markers on reference dies. For example, FIG. 3 shows a top view of a reference die 302 having a fiducial marker 304a that is laser etched onto an upper surface of the die 302. Alternatively, fiducial marker 304b is chemically etched (or plasma etched) onto a surface of the reference die 302. FIG. 4 shows a top view and a cross sectional view of a reference die 402 that has be sawed partially and vertically through an upper surface of the die to create a fiducial marker 404, as similarly exemplified in FIGS. 1-2B. In any example of a fiducial marker, the common denominator is that the fiducial marker comprises a physical alteration of a surface (or of a portion) of the reference die so that an assembly tool or other device can locate the known position of the fiducial marker, and therefore determine the position of the dies for continued manufacturing of the a device. Accordingly, the fiducial marker can take any shape or configuration or be made by any mechanism that renders the marker suitable for use by the piece of equipment that is to commence the next processing step.

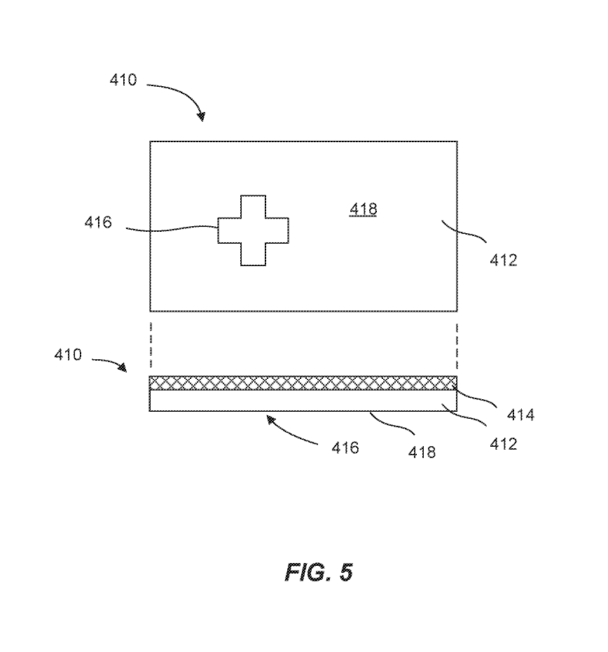

FIG. 5 shows a bottom view and a cross section view of a reference die 410. The cross sectional view illustrates that the reference die comprises a glass layer 412 and a metal coated layer 414 on the glass layer 412. On the bottom of the die 410, the fiducial marker can be an indicia 416 (e.g., a printed or etched symbol) on a lower glass surface 418. In this example, the indicia 416, disposed on the lower surface, such that when the reference die 410 is polished or grinded down during a manufacturing process, the metal layer 414 is removed so that a lithography tool can visibly located the indicia 416 through the remaining transparent glass layer 412.

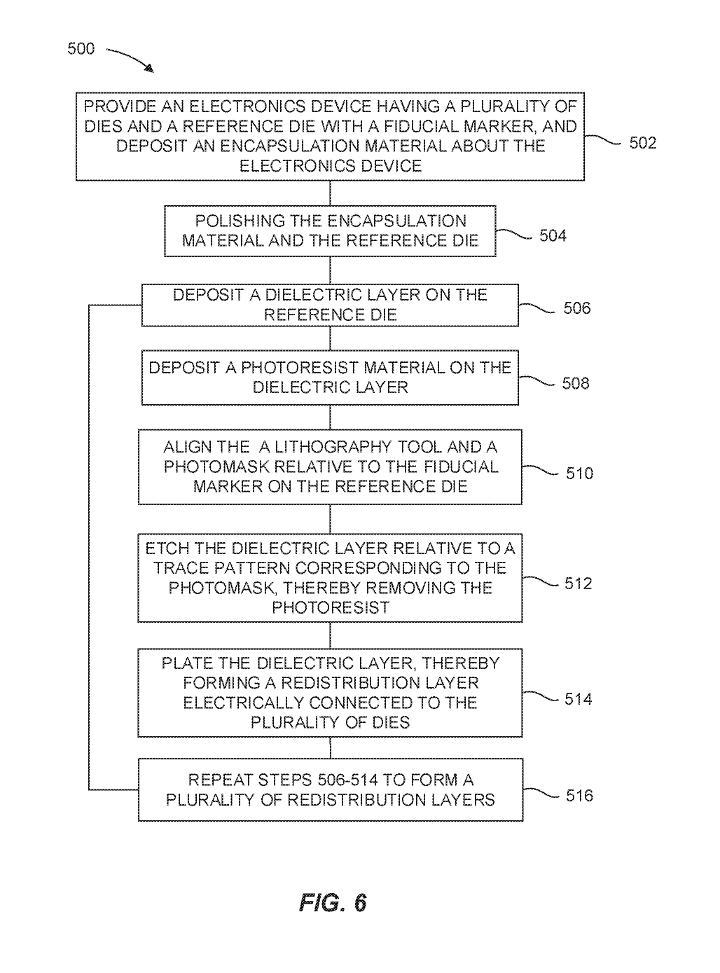

FIG. 6 illustrates a method 500 of aligning an electronics assembly tool with an electronics assembly, as also discussed above. The method can comprise step 502 of providing an electronics device and depositing an encapsulation material about the electronics device. Step 504 comprises polishing the encapsulation material and the reference die after curing the encapsulation material. Step 506 comprises depositing a dielectric layer on the reference die. Step 508 comprises depositing a photoresist material on the dielectric layer, wherein the electronics assembly tool comprises a lithography tool utilizing a photomask and the photoresist material. Step 510 comprises aligning the photomask with the lithography tool relative to the fiducial marker on the reference die. Step 512 comprises etching the dielectric layer relative to a trace pattern corresponding to the photomask, thereby removing the photoresist. Step 514 comprises plating the dielectric layer, thereby forming a redistribution layer electrically connected to the plurality of dies. Step 516 comprises repeat steps 506-514 to form a plurality of redistribution layers.

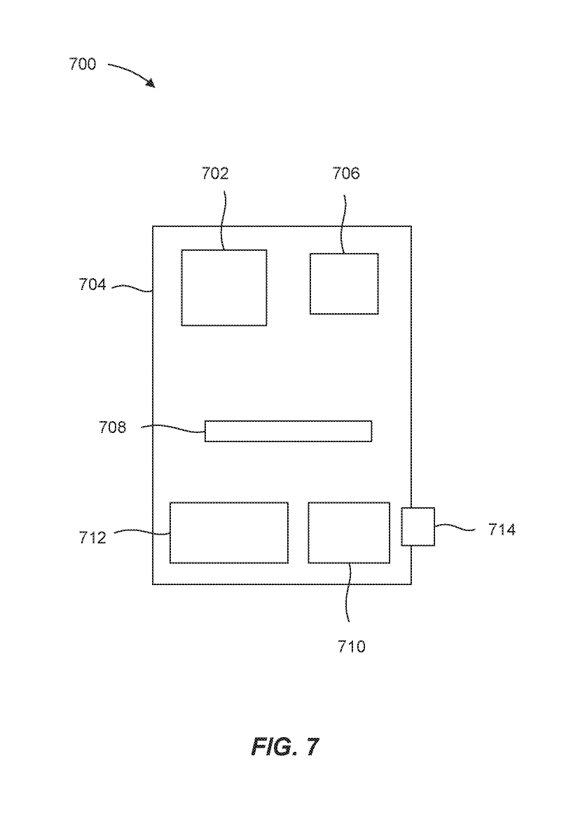

FIG. 7 schematically illustrates an example computing system 700. The computing system 700 can include an electronics device 702 (e.g., and having a fiducial marker) as disclosed herein, coupled to a motherboard 704. In one aspect, the computing system 700 can also include a processor 706, a memory device 708, a radio 710, a cooling system (e.g., a heat sink and/or a heat spreader) 712, a port 714, a slot, or any other suitable device or component, which can be operably coupled to the motherboard 704. The computing system 700 can comprise any type of computing system, such as a desktop computer, a laptop computer, a tablet computer, a smartphone, a server, a wearable electronic device, etc. Other embodiments need not include all of the features specified in FIG. 7, and may include alternative features not specified in FIG. 7.

### Examples

The following examples pertain to further embodiments.

In one example there is provided an electronics device comprising: a substrate; a plurality of dies stacked on the substrate; and a reference die stacked on the plurality of dies, wherein the reference die comprises a fiducial marker that indicates a spatial position of the plurality of dies for alignment of an electronics assembly tool.

In one example of the electronics device, the reference die is a dummy die.

In one example of the electronics device, the fiducial marker comprises a physical alteration of a surface of the reference die.

In one example of the electronics device, the fiducial marker comprises at least one indicia, whereby the at least one indicia is sawed, laser etched, chemically etched, or plasma etched into or onto the reference die.

In one example of the electronics device, the dummy die comprises a metal-coated glass die, wherein the fiducial marker comprises at least one indicia on a glass surface of the metal coated glass die.

In one example, the electronics device further comprises a dielectric layer disposed on the reference die.

In one example of the electronics device, the dielectric layer comprises a transparent material such that the fiducial marker is locatable by the electronics assembly tool.

In one example of the electronics device, the electronics device includes a vertical wire interconnect structure coupled to the plurality of dies.

In one example of the electronics device, the dielectric layer is etched corresponding to a photomask after a photoresist is disposed on the dielectric layer.

In one example of the electronics device, the etched dielectric layer comprises at least one redistribution layer electrically coupled to the vertical wire interconnect structure.

In one example there is provided a method of aligning an electronics assembly tool with an electronics assembly. The method comprises: providing an electronics device as recited herein; and positioning the electronics device proximate the electronics assembly tool such that the electronics assembly tool identifies the three dimensional position of the fiducial marker for alignment of the electronics assembly tool.

In one example, the method of aligning the electronics assembly tool further comprises depositing and curing an encapsulation material about the electronics assembly.

In one example, the method of aligning the electronics assembly tool further comprises polishing the encapsulation material and the reference die after curing the encapsulation material.

In one example, the method of aligning the electronics assembly tool further comprises depositing a dielectric layer on the reference die.

In one example, the method of aligning the electronics assembly tool further comprises depositing a photoresist material on the dielectric layer, wherein the electronics assembly tool comprises a lithography tool utilizing a photomask and the photoresist material.

In one example, the method of aligning the electronics assembly tool further comprises aligning the photomask with the lithography tool relative to the fiducial marker on the reference die.

In one example, the method of aligning the electronics assembly tool further comprises etching the dielectric layer relative to a trace pattern corresponding to the photomask, thereby removing the photoresist.

In one example, the method of aligning the electronics assembly tool further comprises plating the dielectric layer, thereby forming a redistribution layer electrically connected to the plurality of dies.

In one example, the method of aligning the electronics assembly tool further comprises forming a plurality of redistribution layers by repeating the prior seven steps.

In one example of the method of aligning the electronics assembly tool, the fiducial marker is formed either before assembly of the electronics device or after the reference die is stacked on the plurality of dies.

In one example of the method of aligning the electronics assembly tool, the reference die is a dummy die and the fiducial marker comprises a physical alteration of a surface of the reference die.

In one example of the method of aligning the electronics assembly tool, the fiducial marker comprises at least one indicia, whereby the at least one indicia is sawed, laser etched, chemically etched, or plasma etched into or onto the reference die.

In one example there is provided a method of making an electronics device having a fiducial marker. The method comprises: providing a plurality of dies on a substrate of an electronics assembly; positioning a reference die on top of the plurality of dies; and forming a fiducial marker on the reference die before or after positioning the reference die, wherein the fiducial marker indicates spatial position of the electronics assembly for alignment of an electronics assembly tool.

In one example, the method of making the electronics device further comprises depositing and curing an encapsulation material about the electronics assembly.

In one example, the method of making the electronics device further comprises polishing the encapsulation material and the reference die after curing the encapsulation material.

In one example, the method of making the electronics device further comprises depositing a dielectric layer on the reference die.

In one example, the method of making the electronics device further comprises depositing a photoresist material on the dielectric layer, wherein the electronics assembly tool comprises a lithography tool utilizing a photomask and the photoresist material.

In one example, the method of making the electronics device further comprises aligning the photomask with the lithography tool relative to the fiducial marker on the reference die.

In one example, the method of making the electronics device further comprises etching the dielectric layer relative to a trace pattern corresponding to the photomask, thereby removing the photoresist.

In one example, the method of making the electronics device further comprises plating the dielectric layer, thereby forming a redistribution layer electrically connected to the plurality of dies.

In one example there is provided a method of forming a plurality of redistribution layers by repeating the steps of the prior seven steps.

In one example of the method of making the electronics assembly, the fiducial marker is formed either before assembly of the electronics device or after the reference die is stacked on the plurality of dies.

In one example of the method of making the electronics assembly, the reference die is a dummy die and the fiducial marker comprises a physical alteration of a surface of the reference die.

In one example of the method of making the electronics assembly, the fiducial marker comprises at least one indicia, whereby the at least one indicia is sawed, laser etched, chemically etched, or plasma etched into or onto the reference die.

In one example there is provided a method of aligning a lithography mask relative to a die stack. The method comprises: providing a plurality of dies stacked on a substrate of an electronics assembly, and a reference die on top of the plurality of dies, wherein the reference die includes a fiducial marker that indicates spatial position of the electronics assembly; and aligning a photomask with a lithography tool relative to the fiducial marker on the reference die.

In one example, the method of aligning the lithography mask further comprises forming the fiducial marker on the reference die before or after positioning the reference die on top of the plurality of dies.

In one example, the method of aligning the lithography mask further comprises depositing and curing an encapsulation material about the electronics assembly before aligning the photomask.

In one example, the method of aligning the lithography mask further comprises polishing the encapsulation material and the reference die after curing the encapsulation material.

In one example, the method of aligning the lithography mask further comprises depositing a dielectric layer on the reference die after polishing the encapsulation material.

In one example, the method of aligning the lithography mask further comprises depositing a photoresist material on the dielectric layer, wherein the lithography tool utilizes the photoresist material.

In one example, the method of aligning the lithography mask further comprises etching the dielectric layer relative to a trace pattern corresponding to the photomask, thereby removing the photoresist material.

In one example, the method of aligning the lithography mask further comprises plating the dielectric layer, thereby forming a redistribution layer electrically connected to the plurality of dies.

In one example, the method of aligning the lithography mask further comprises forming a plurality of redistribution layers by repeating the prior seven steps.

In one example of the method of aligning the lithography mask, the fiducial marker is formed either before assembly of the electronics device or after the reference die is stacked on the plurality of dies.

In one example of the method of aligning the lithography mask, the reference die is a dummy die and the fiducial marker comprises a physical alteration of a surface of the reference die.

In one example of the method of aligning the lithography mask, the fiducial marker comprises at least one indicia, whereby the at least one indicia is sawed, laser etched, chemically etched, or plasma etched into or onto the reference die.

In one example there is provided a system for aligning an electronics assembly tool relative to an electronic device. The system comprises: an electronic device having: a substrate; a plurality of dies stacked on the substrate; and a reference die stacked on the plurality of dies, wherein the reference die comprises a fiducial marker; and an electronics assembly tool positionable in three dimensional space relative to the electronic device, wherein the fiducial marker indicates the spatial position of the electronic device for alignment of the electronics assembly tool for performing operations on the electronic assembly.

In one example of the system, the reference die is a dummy die.

In one example of the system, the fiducial marker comprises a physical alteration of a surface of the reference die.

In one example of the system, the fiducial marker comprises at least one indicia, whereby the at least one indicia is sawed, laser etched, chemically etched, or plasma etched into or onto the reference die.

In one example of the system, the electronics device includes a vertical wire interconnect structure coupled to the plurality of dies.

In one example of the system, the electronic device comprises at least one redistribution layer electrically coupled to the vertical wire interconnect structure.

In one example of the system, the electronics assembly tool comprises a lithography tool.

In one example, there is provided a computing system comprising a motherboard, and an electronics device operably coupled to the motherboard. The electronics device comprises a substrate; a plurality of dies stacked on the substrate; and a reference die stacked on the plurality of dies, wherein the reference die comprises a fiducial marker that indicates a spatial position of the plurality of dies for alignment of an electronics assembly tool.

In one example of a computing system, the computing system comprises a desktop computer, a laptop, a tablet, a smartphone, a server, a wearable electronic device, or a combination thereof.

In one example of a computing system, the computing system further comprises a processor, a memory device, a heat sink, a radio, a slot, a port, or a combination thereof operably coupled to the motherboard.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. An electronics device comprising:
a substrate;
a plurality of dies stacked on the substrate; and
a reference die stacked on the plurality of dies, wherein the reference die comprises a dummy die having a fiducial marker that indicates a spatial position of the plurality of dies for alignment of an electronics assembly tool.

2. (canceled)

3. The device of claim 1, wherein the fiducial marker comprises a physical alteration of a surface of the reference die.

4. The device of claim 3, wherein the fiducial marker comprises at least one indicia, whereby the at least one indicia is sawed, laser etched, chemically etched, or plasma etched into or onto the reference die.

5. The device of claim 1, wherein the dummy die comprises a metal coated glass die, wherein the fiducial marker comprises at least one indicia on a glass surface of the metal coated glass die.

6. The device of claim 1, further comprising a dielectric layer disposed on the reference die.

7. The device of claim 6, wherein the dielectric layer comprises a transparent material such that the fiducial marker is locatable by the electronics assembly tool.

8. The device of claim 7, wherein the electronics device includes a vertical wire interconnect structure coupled to the plurality of dies.

9. The device of claim 8, wherein the dielectric layer is etched corresponding to a photomask after a photoresist is disposed on the dielectric layer.

10. The device of claim 9, wherein the etched dielectric layer comprises at least one redistribution layer electrically coupled to the vertical wire interconnect structure.

11. A method of making an electronics device having a fiducial marker, the method comprising:
providing a plurality of dies on a substrate of an electronics assembly;
positioning a reference die on top of the plurality of dies; and
forming a fiducial marker on the reference die before or after positioning the reference die, wherein the fiducial marker indicates spatial position of the electronics assembly for alignment of an electronics assembly tool.

12. The method of claim 11, further comprising depositing and curing an encapsulation material about the electronics assembly.

13. The method of claim 12, further comprising polishing the encapsulation material and the reference die after curing the encapsulation material.

14. The method of claim 13, further comprising depositing a dielectric layer on the reference die.

15. The method of claim 14, further comprising depositing a photoresist material on the dielectric layer, wherein the electronics assembly tool comprises a lithography tool utilizing a photomask and the photoresist material.

16. The method of claim 15, further comprising aligning the photomask with the lithography tool relative to the fiducial marker on the reference die.

17. The method of claim 15, further comprising etching the dielectric layer relative to a trace pattern corresponding to the photomask, thereby removing the photoresist.

18. The method of claim 11, further comprising plating the dielectric layer, thereby forming a redistribution layer electrically connected to the plurality of dies.

19. A method of aligning a lithography mask relative to a die stack, the method comprising:
providing a plurality of dies stacked on a substrate of an electronics assembly, and a reference die on top of the plurality of dies, wherein the reference die includes a fiducial marker that indicates spatial position of the electronics assembly; and
aligning a photomask with a lithography tool relative to the fiducial marker on the reference die.

20. The method of claim 19, further comprising forming the fiducial marker on the reference die before or after positioning the reference die on top of the plurality of dies.

21. The method of claim 19, further comprising depositing and curing an encapsulation material about the electronics assembly before aligning the photomask.

22. The method of claim 21, further comprising polishing the encapsulation material and the reference die after curing the encapsulation material.

23. The method of claim 22, further comprising depositing a dielectric layer on the reference die after polishing the encapsulation material.

24. The method of claim 23, further comprising depositing a photoresist material on the dielectric layer, wherein the lithography tool utilizes the photoresist material.

25. The method of claim 24, further comprising etching the dielectric layer relative to a trace pattern corresponding to the photomask, thereby removing the photoresist material.

26. The method of claim 25, further comprising plating the dielectric layer, thereby forming a redistribution layer electrically connected to the plurality of dies.
